(19) United States
(12) Patent Application Publication
(10) Pub. No.: US 2023/0133916 A1
(43) Pub. Date: May 4, 2023

(54) PROCESS OF SURFACE TREATMENT OF SOI WAFER

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Ziwen WANG, Shanghai (CN); Minghao LI, Shanghai (CN); Meng CHEN, Shanghai (CN); Hongtao XU, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 17/586,254

(22) Filed: Jan. 27, 2022

(30) Foreign Application Priority Data
Oct. 29, 2021 (CN) 202111273132.8

(51) Int. Cl. H01L 21/762

(52) U.S. Cl. CPC H01L 21/76254; H01L 21/76256; H01L 21/76243

(57) ABSTRACT

The present application provides a process of surface treatment of a silicon-on-insulator (SOI) wafer comprising: providing a SOI wafer comprising a back substrate, a top silicon layer and an insulating buried layer, wherein the insulating buried layer is located between the back substrate and the top silicon layer, and the top silicon layer has a surface roughness of larger than 10 Å; conducting a first planarization to a surface of the top silicon layer by conducting a batch annealing process at a first target temperature, and conducting a second planarization to a surface of the top silicon layer by conducting a rapid thermal annealing process at a second target temperature. The present application combines the batch annealing process and the rapid thermal annealing process to optimize the SOI wafer, especially the surface roughness of the SOI wafer. The SOI wafer planarized by the two thermal annealing processes has a good surface roughness of the top silicon layer which satisfies process requirements.

### BACKGROUND OF THE INVENTION

### 1. Field of the Invention

The present invention relates to semiconductor manufacture, and more particularly to surface treatment of SOI wafer.

### 2. Description of the Related Art

With the development of post-Moore period, the requests for structure, thickness uniformity and the surface flatness of silicon-on-insulator (SOI) become more strict. Currently, SOI can be broadly applied in the technical fields of microelectronics, optics and optoelectronics, but the challenges for SOI materials increases correspondingly. In SOI, at least one layer of buried oxidation layer is introduced between a top silicon layer and a back substrate. It is requested that an advanced SOI device has a top silicon layer as thinner as possible. However, chemical mechanical polishing (CMP) conventionally applied to thinning and planarization processes causes non-uniform thickness of the top silicon layer, resulting in introduction of additional surface defects.

To solve the above problems in planarization, a thermal annealing treatment is applied to replace the conventional CMP to planarize the surface of the top silicon layer. The thermal annealing treatment includes the batch annealing treatment and the rapid thermal annealing treatment. Advantages of the batch annealing includes that the wafer is planarized by reduce the relative height of long-term fluctuations of the wafer surface topography during a long time period, while advantages of the rapid thermal annealing includes that the wafer is planarized by reduce the relative height of short-term fluctuations of the wafer surface topography during a short time period. Surface roughness of the SOI is the main evaluation standard of thermal annealing process because it significantly affects the performance of the back-end device. Conventionally, the thermal annealing process for SOI is conducted under atmosphere of a mixture of argon and hydrogen, wherein hydrogen is mainly to prevent the existence of oxygen or/and oxide. The oxygen and oxide during whole anneal process causes deteriorated granulation on the surface of the top silicon layer. However, the silicon surface is etched by hydrogen at high temperature. U.S. Pat. No. 8,389,412 B2 discloses an incorporation of a rapid thermal annealing process and an oxidation thinning process. The wafer is sequentially subjected to the rapid thermal annealing, the oxidation thinning, the rapid thermal annealing, and the oxidation thinning The above process can reduce surface roughness of the SOI wafer with a certain degree, however, the obtained surface roughness cannot meet the process requirements because of the limitation for the fluctuations during a short time period. In addition, the oxidation thinning can improve the surface roughness insignificantly because one thermal treatment is conducted previously.

### SUMMARY

The purpose of the present application is to provide a process of surface treatment of SOI (silicon-on-insulator) wafer to eliminate the negative effect to the SOI wafer caused by hydrogen during the planarization, and optimize the wafer surface roughness.

For the above purpose, the present application provides a process of surface treatment of a SOI wafer comprising:
providing a SOI wafer comprising a back substrate, a top silicon layer and an insulating buried layer, wherein the insulating buried layer is located between the back substrate and the top silicon layer, and the top silicon layer has a surface roughness of larger than 10 Å;
conducting a first planarization to a surface of the top silicon layer by conducting a batch annealing process at a first target temperature, and
conducting a second planarization to a surface of the top silicon layer by conducting a rapid thermal annealing process at a second target temperature.

In one embodiment, the batch annealing process comprises: loading the SOI wafer into a batch vertical furnace under atmosphere of argon; conducting an heating-up period under atmosphere of a mixture of argon and hydrogen; and
conducting the first planarization to a surface of the top silicon layer by the batch annealing process while the first target temperature is reached, wherein the atmosphere for the batch annealing process is argon or a mixture of argon and hydrogen.

In one embodiment, the step of loading is conducted at a loading temperature of 500° C.-800° C., the heating-up period is conducted with an increase rate of 0.5° C./min-20° C./min, and the batch annealing process is conducted at 1050° C.-1250° C. for 1 minute (min) −120 min.

In one preferred embodiment, the step of loading is conducted at a loading temperature of 650° C.; the heating-up period is conducted with an increase rate of 5° C./min-10° C./min; and the batch annealing process is conducted at 1100° C.-1200° C. for 30 min-60 min

In one embodiment, the rapid thermal annealing process comprises: heating the SOI wafer loaded in a rapid thermal annealing chamber under atmosphere of a mixture of argon and hydrogen; and
conducting the second planarization to the surface of the top silicon layer by the rapid thermal annealing process while the second target temperature is reached, wherein the atmosphere for the rapid thermal annealing process is argon or a mixture of argon and hydrogen.

In one embodiment, the rapid thermal annealing chamber has a low pressure or a normal pressure, for example, a pressure of 1 mbar-1010 mbar.

In one embodiment, the temperature of the rapid thermal annealing process, i.e. the second target temperature, is 1100° C.-1300° C., and the treatment time of the rapid thermal annealing is 1 second (s)-120 s.

In one preferred embodiment, the second target temperature is 1150° C.-1250° C., and the rapid thermal annealing time is 10 s-60 s.

In one embodiment, the mixture of argon and hydrogen comprises less than 10% of hydrogen.

In one preferred embodiment, the mixture of argon and hydrogen comprises less than 3% of hydrogen.

In one embodiment, after the rapid thermal annealing process, the process further comprises:
growing a silicon oxide film on the surface of the top silicon layer by conducting a thermal oxidation process, and;
removing the silicon oxide film by wet etching.

Compared with the conventional technologies, the present application provides the following advantages.

The present application provides a process of surface treatment of a SOI wafer comprising: providing a SOI wafer comprising a back substrate, a top silicon layer and an insulating buried layer, wherein the insulating buried layer is located between the back substrate and the top silicon layer, and the top silicon layer has a surface roughness of larger than 10 Å; conducting a first planarization to a surface of the top silicon layer by conducting a batch annealing process at a first target temperature, and conducting a second planarization to a surface of the top silicon layer by conducting a rapid thermal annealing process at a second target temperature. The present application combines the batch annealing process and the rapid thermal annealing process to optimize the SOI wafer, especially the surface roughness of the SOI wafer. The SOI wafer planarized by the two thermal annealing processes has a good surface roughness of the top silicon layer which satisfies process requirements.

Moreover, the present application combines the batch annealing process, the rapid thermal annealing process and the thermal oxidation process to further optimize the SOI wafer, especially the surface roughness of the SOI wafer. The SOI wafer planarized by the two thermal annealing processes has a good surface roughness of the top silicon layer which satisfies process requirements. The process of the present application can be simplified and the cost can be reduced.

### BRIEF DESCRIPTION OF THE DRAWINGS

FIG. 1 is a flowchart illustrating process steps for surface treatment of SOI wafer according to one embodiment of the present application.

FIG. 2a-2d are AFM 10 μm*10 μm scanning photographs of the surface of the top silicon layer of SOI wafer according to one embodiment of the present application.

### DETAILED DESCRIPTION OF THE EMBODIMENTS

To fully understand the present application, detailed structures or steps of the process of surface treatment of the SOI wafer are set forth in the following descriptions to explain the technical solutions of the present application. The implementation of the present application is not limited by the specific detail known by a person having ordinary skills in the art. The preferred embodiments of the present application are described in detail below, but the present application may have other embodiments in addition to the detailed description.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

For easy understanding of the purpose and features of the present invention, the embodiments of the present invention will be further described below with reference to the accompanying drawings. It should be specified that the drawings are provided with very simplified form and imprecise ratios for convenient and clear assistance in explaining the embodiments.

### EXAMPLES

### Example 1

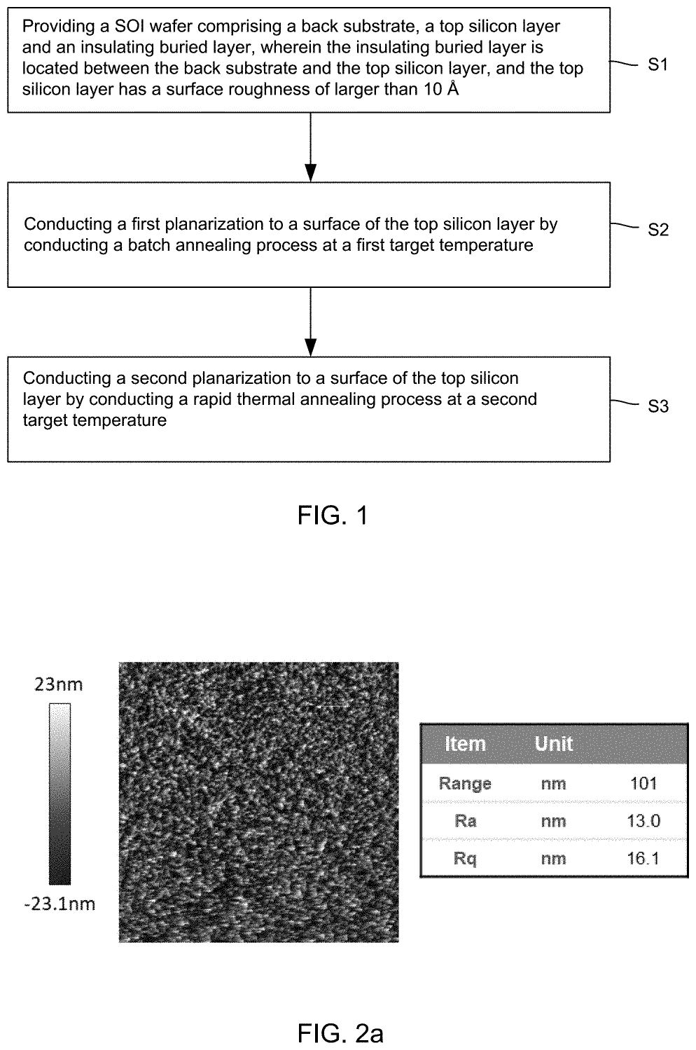

FIG. 1 is a flowchart illustrating process steps for surface treatment of SOI wafer. As shown in FIG. 1, the process of surface treatment of a SOI wafer provided in Example 1 comprises the following steps.

Step S1: providing a SOI wafer comprising a back substrate, a top silicon layer and an insulating buried layer, wherein the insulating buried layer is located between the back substrate and the top silicon layer, and the top silicon layer has a surface roughness of larger than 10 Å;

Step S2: conducting a first planarization to a surface of the top silicon layer by conducting a batch annealing process at a first target temperature, and

Step S3: conducting a second planarization to a surface of the top silicon layer by conducting a rapid thermal annealing process at a second target temperature.

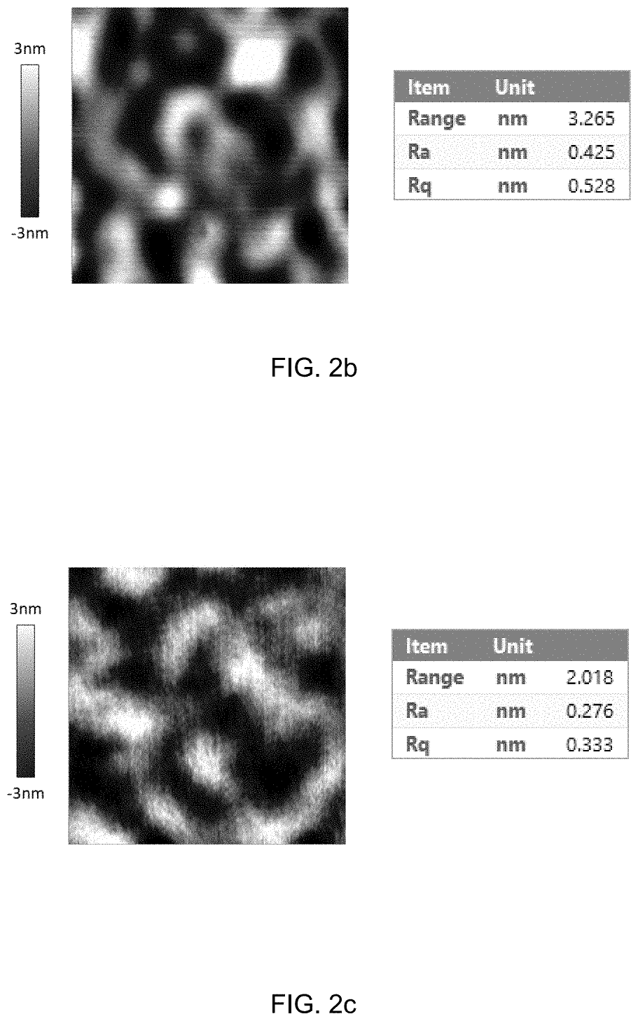

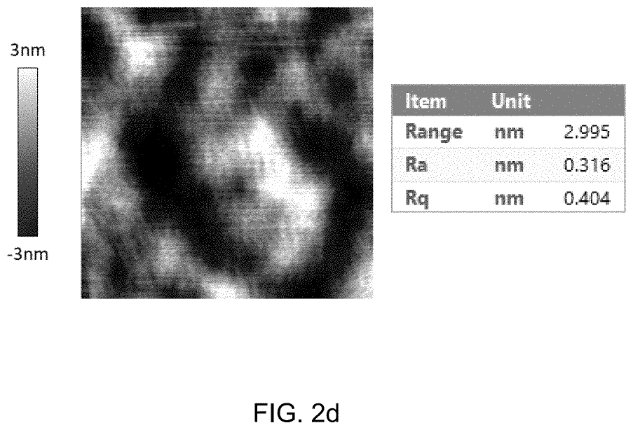

Referring FIG. 1 and FIG. 2a-2d, the process of surface treatment of a SOI wafer is further described as follows.

The step S1 is conducted to provide a SOI wafer. The SOI wafer comprising a back substrate, a top silicon layer and an insulating buried layer, wherein the insulating buried layer is located between the back substrate and the top silicon layer, and the top silicon layer has a surface roughness of larger than 10 Å.

Specifically, the step S1 comprises the following steps.

First, a bonding SOI wafer is provided. The bonding SOI wafer comprises an initial top silicon layer, an insulating buried layer and a back substrate, wherein the insulating buried layer is located between the initial top silicon layer and the back substrate. A damage layer is formed in the initial top silicon layer.

The surface of the initial top silicon layer opposite to the insulating buried layer is subjected to an initial annealing process, so that the SOI wafer can be peeled from and along with the damage layer. At this time, the surface of the initial top silicon layer opposite to the insulating buried layer has a surface roughness larger than 10 Å because of the peel-off process.

Then, the step S2 is conducted. At a first target temperature, a first planarization to the surface of the top silicon layer by the batch annealing process is conducted.

Specifically, the following steps are included. First, the SOI wafer is loaded into a batch vertical furnace. The loading temperature is 500° C.-800° C., and the preferable temperature is 650° C. The time period for maintenance of the loading temperature is 1 minute (min)-10 min, and the preferable time period is 5 min The loading atmosphere is argon only, i.e. pure argon.

Then, a first heating-up period is initiated. At the same time, the atmosphere is switched from pure argon to a mixture of argon and hydrogen. The gas mixture comprises less than 10% of hydrogen, and preferably less than 3% of hydrogen. The first heating-up period has a heating rate of 0.5° C./min-20° C./min, and preferably 5° C./min-10° C./min In this step, the concentration of hydrogen in the gas mixture is optimized and improved to reduce the negative effects to the SOI wafer caused by hydrogen.

While the first target temperature is reached, a first isothermal stage is started. During the first isothermal stage, the batch treatment is conducted. In this step, the atmosphere of the first isothermal stage can be still the mixture of argon and hydrogen, in which the concentration of hydrogen is less than 10%, and preferably less than 3% of hydrogen. Alternatively, the atmosphere of the first isothermal stage can be switched to pure argon. The first target temperature is 1050° C.-1250° C., and preferably 1100° C.-1200° C. The time period for the batch annealing process is 1 min-120 min, and preferably 30 min-60 min

While the atmosphere is switched to pure argon, a cooling step is initiated. The cooling rate is 1° C./min-10° C./min, and preferably 3° C./min-5° C./min The cooling step is conducted until the temperature is decreased to the device temperature, i.e. 500° C.-800° C., and preferably 650° C., to complete the first planarization to the surface of the top silicon layer.

Compared with the conventional technologies, this example combines the batch annealing process and the rapid thermal annealing process to optimize the SOI wafer, especially the surface roughness of the SOI wafer.

Then, the step S3 is conducted. At the second target temperature, a second planarization is conducted to the surface of the top silicon layer by a rapid thermal annealing process.

Specifically, the following steps are included.

First, the SOI wafer is loaded into a rapid thermal annealing chamber, and a rapid heating-up period, i.e. the second heating-up period, is initiated. The atmosphere of the second heating-up period is a mixture of argon and hydrogen. The gas mixture comprises less than 10% of hydrogen, and preferably less than 3% of hydrogen.

While the second target temperature is reached, a second isothermal stage is started. During the second isothermal stage, the atmosphere of the second isothermal stage can be still the mixture of argon and hydrogen, in which the concentration of hydrogen is less than 10%, and preferably less than 3% of hydrogen. Alternatively, the atmosphere of the second isothermal stage can be switched to pure argon. The rapid thermal annealing chamber has a low pressure or a normal pressure, for example, a pressure of 1 mbar-1010 mbar. The second target temperature is 1100° C.-1300° C., and preferably 1150° C.-1250° C. The time period for the rapid thermal annealing process is 1 s-120 s, and preferably 10 s-60 s.

In one embodiment, after the step S3, a thermal oxidation process is conducted to grow a silicon oxide film on the surface of the top silicon layer opposite to the insulating buried layer. The atmosphere of oxygen can be dry oxygen, wet oxygen, or a mixture thereof.

Then, the silicon oxide film is removed by wet etching, thereby the thinning process of the top silicon layer can be completed. Simultaneously, the SOI wafer, especially the surface roughness of the SOI wafer, can be optimized. The wet etching process can be conducted in a solution of hydrogen fluoride (HF). The concentration of HF is less than 20%, and the preferable HF concentration is 5%.

The example is provided as follows.

Referring FIG. 2a, a SOI wafer after the peel-off process is provided. Because of the peel-off process, the SOI wafer has a top silicon layer with a larger surface roughness. It is known that the surface of the top silicon layer opposite to the insulating buried layer has a surface roughness of 161 A by using non-contact scanning of atomic force microscope (AFM) 10 μm*10 μm.

The SOI wafer is then loaded into a batch vertical furnace at the loading temperature of 650° C. under the atmosphere of pure argon with the maintenance time period of 5 min Heating of the furnace is conducted for the first heating-up period at a heating rate of 5° C./min, and the atmosphere is simultaneously switched to a mixture of argon and hydrogen, in which the concentration of hydrogen is 2.5%. The first annealing process is started at 1100° C., the atmosphere is switched to pure argon, and the annealing time is 40 min Then, cooling is conducted with a cooling rate of 1° C./min-5° C./min under the atmosphere of argon until the temperature is decreased to 650° C. Accordingly, the surface of the top silicon layer opposite to the insulating buried layer has a surface roughness of 5.3 A by using non-contact scanning of AFM 10 μm*10 μm, as shown in FIG. 2b.

Subsequently, the rapid thermal annealing process is conducted to the SOI wafer. The atmosphere in the heating step is a mixture of argon and hydrogen, in which the concentration of hydrogen is 2.5%. In the annealing step, the atmosphere is switched to pure argon, the annealing is conducted at 1200° C. for 30 s. Accordingly, the surface of the top silicon layer opposite to the insulating buried layer has a surface roughness of 3.3 Å by using non-contact scanning of AFM 10 μm*10 μm, as shown in FIG. 2c.

Then, a silicon oxide film is grown on the surface of the top silicon layer under the atmosphere of wet oxygen. The silicon oxide film is removed by wet etching with 5% of HF solution, and the top silicon layer is thinned. Accordingly, the surface of the top silicon layer opposite to the insulating buried layer has a surface roughness of 4.0 Å by using non-contact scanning of AFM 10 μm*10 μm, as shown in FIG. 2d.

According to the above, the present application provides a process of surface treatment of a SOI wafer. The present application combines the batch annealing process and the rapid thermal annealing process, and optimize the hydrogen concentration of the gas mixture, such that the SOI wafer planarized by the two thermal annealing processes has a good surface roughness of the top silicon layer which satisfies process requirements. Specifically, this solution can provide the SOI wafer with a surface roughness of the top silicon layer less than 5 Å, and further optimizes the process and reduce the cost.

It should be noted that, unless otherwise specified or indicated, the description of the terms “first”, “second”, and “third” in the specification are only used to distinguish each component, element, step and the like in the specification, but not to indicate the logical relationship or sequence relationship between these components, elements, steps and the like.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A process of surface treatment of a silicon-on-insulator (SOI) wafer comprising:
providing a SOI wafer comprising a back substrate, a top silicon layer and an insulating buried layer, wherein the insulating buried layer is located between the back substrate and the top silicon layer, and the top silicon layer has a surface roughness of larger than 10 Å;
conducting a first planarization to a surface of the top silicon layer by conducting a batch annealing process at a first target temperature, and conducting a second planarization to a surface of the top silicon layer by
conducting a rapid thermal annealing process at a second target temperature.

2. The process of claim 1, wherein the batch annealing process comprises:
loading the SOI wafer into a batch vertical furnace under atmosphere of argon;
conducting an heating-up period under atmosphere of a mixture of argon and hydrogen; and
conducting the first planarization to a surface of the top silicon layer by the batch annealing process while the first target temperature is reached, wherein the atmosphere for the batch annealing process is argon or a mixture of argon and hydrogen.

3. The process of claim 2, wherein
the step of loading is conducted at a loading temperature of 500° C.-800° C.;
the heating-up period is conducted with an increase rate of 0.5° C./min-20° C./min; and
the batch annealing process is conducted at 1050° C.-1250° C. for 1 min-120 min.

4. The process of claim 3, wherein
the step of loading is conducted at a loading temperature of 650° C.;
the heating-up period is conducted with an increase rate of 5° C./min-10° C./min; and
the batch annealing process is conducted at 1100° C.-1200° C. for 30 min-60 min.

5. The process of claim 1, wherein the rapid thermal annealing process comprises:
heating the SOI wafer loaded in a rapid thermal annealing chamber under atmosphere of a mixture of argon and hydrogen; and
conducting the second planarization to the surface of the top silicon layer by the rapid thermal annealing process while the second target temperature is reached, wherein the atmosphere for the rapid thermal annealing process is argon or a mixture of argon and hydrogen.

6. The process of claim 1, wherein the rapid thermal annealing chamber has a pressure of 1 mbar-1010 mbar.

7. The process of claim 1, wherein the second target temperature is 1100° C.-1300° C., and the rapid thermal annealing time is 1 s-120 s.

8. The process of claim 7, wherein the second target temperature is 1150° C.-1250° C., and the rapid thermal annealing time is 10 s-60 s.

9. The process of claim 1, wherein the mixture of argon and hydrogen comprises less than 10% of hydrogen.

10. The process of claim 9, wherein the mixture of argon and hydrogen comprises less than 3% of hydrogen.

11. The process of claim 1, further comprises:
after the rapid thermal annealing process, growing a silicon oxide film on the surface of the top silicon layer by conducting a thermal oxidation process, and;
removing the silicon oxide film by wet etching.
